(19) United States
(12) Patent Application Publication
(10) Pub. No.: US 2014/0174349 A1
(43) Pub. Date: Jun. 26, 2014

(54) APPARATUS AND METHODS OF MIXING AND DEPOSITING THIN FILM PHOTOVOLTAIC COMPOSITIONS

(71) Applicant: Global Solar Energy, Inc., Tucson, AZ (US)

(72) Inventors: Jeffrey S. BRITT, Tucson, AZ (US); Scott WIEDEMAN, Tucson, AZ (US)

(73) Assignee: Global Solar Energy, Inc., Tucson, AZ (US)

(21) Appl. No.: 14/194,407

(22) Filed: Feb. 28, 2014

Related U.S. Application Data
(63) Continuation of application No. 12/980,185, filed on Dec. 28, 2010.

(51) Int. Cl. H01L 31/18

(52) U.S. Cl. CPC H01L 31/18
USPC 118/696; 118/718; 118/712; 118/726

(57) ABSTRACT

Improved methods and apparatus for forming thin-film layers of semiconductor material absorber layers on a substrate web. According to the present teachings, a semiconductor layer may be formed in a multi-zone process whereby various layers are deposited sequentially onto a moving substrate web. At least one layer is deposited from a mixed gallium indium source.

### CROSS-REFERENCE TO RELATED APPLICATIONS

This application is a continuation of U.S. patent application Ser. No. 12/980,185, filed Dec. 28, 2010, which claims priority under 35 U.S.C. §119 and applicable foreign and international law of U.S. Provisional Patent Application Ser. No. 61/284,925, filed Dec. 28, 2009, which is hereby incorporated by reference in its entirety. Also incorporated by reference in their entireties are the following patent and patent application: U.S. Pat. No. 7,194,197, Ser. No. 12/424,497 filed Apr. 15, 2009.

### BACKGROUND

The field of photovoltaics generally relates to multi-layer materials that convert sunlight directly into DC electrical power. The basic mechanism for this conversion is the photovoltaic effect, first observed by Antoine-Cesar Becquerel in 1839, and first correctly described by Albert Einstein in a seminal 1905 scientific paper for which he was awarded a Nobel Prize for physics. In the United States, photovoltaic (PV) devices are popularly known as solar cells or PV cells. Solar cells are typically configured as a cooperating sandwich of positive, or p-type and negative, or n-type semiconductors, in which the n-type semiconductor material (on one “side” of the sandwich) exhibits an excess of electrons, and the p-type semiconductor material (on the other “side” of the sandwich) exhibits an excess of holes, each of which signifies the absence of an electron. Near the p-n junction between the two materials, valence electrons from the n-type layer move into neighboring holes in the p-type layer. This creates a carrier depletion zone and a small electrical field in the vicinity of the metallurgical junction that forms the electronic p-n junction. The resulting potential across the junction inhibits further migration of carriers, and any electrons that appear are swept into the n region and any holes that appear are swept into the p region.

When an incident photon excites an electron in the cell into its conduction band, the excited electron becomes unbound from the atoms of the semiconductor, creating a free electron/hole pair. Because, as described above, the p-n junction creates an electric field in the vicinity of the junction, electron/hole pairs created in this manner near the junction tend to separate and move away from junction, with the electron moving toward the n-type side, and the hole moving toward the p-type side of the junction. This creates an overall charge imbalance in the cell, so that if an external conductive path is provided between the two sides of the cell, electrons will move from the n side back to the p side along the external path, creating a useful electric current. In practice, electrons may be collected from at or near the surface of the n side by a conducting grid that covers a portion of the surface, while still allowing sufficient access into the cell by incident photons.

Such a photovoltaic structure, when appropriately located electrical contacts are included, and the cell (or a series of cells) is incorporated into a closed electrical circuit, forms a working PV device. As a standalone device, a single conventional solar cell is not sufficient to power most applications. As a result, solar cells are commonly arranged into PV modules, or “strings,” by connecting the front of one cell to the back of another, thereby adding the voltages of the individual cells together in electrical series. Typically, a significant number of cells are connected in series to achieve a usable voltage. The resulting DC current then may be fed through an inverter, where it is transformed into AC current at an appropriate frequency, which is chosen to match the frequency of AC current supplied by a conventional power grid. In the United States, this frequency is 60 Hertz (Hz), and most other countries provide AC power at either 50 Hz or 60 Hz.

One particular type of solar cell that has been developed for commercial use is a “thin-film” PV cell. In comparison to other types of PV cells, such as crystalline silicon PV cells, thin-film PV cells require less light-absorbing semiconductor material to create a working cell, and thus can reduce processing costs. Thin-film based PV cells also offer reduced cost by employing previously developed deposition techniques for the electrode layers, since similar materials are widely used in the thin-film industry for protective, decorative, and functional coatings. Common examples of low cost commercial thin-film products include water impermeable coatings on polymer-based food packaging, decorative coatings on architectural glass, low emissivity thermal control coatings on residential and commercial glass, and scratch and anti-reflective coatings on eyewear. Adopting or modifying techniques that have been developed in these other fields has allowed a reduction in development costs for PV cell thin-film deposition techniques.

Furthermore, thin-film cells have exhibited efficiencies approaching 20%, which rivals or exceeds the efficiencies of the most efficient crystalline cells. In particular, the semiconductor material copper indium gallium diselenide (CIGS) is stable, has low toxicity, and is truly a thin film, requiring a thickness of less than two microns in a working PV cell. As a result, to date CIGS appears to have demonstrated the greatest potential for high performance, low cost thin-film PV products, and thus for penetrating bulk power generation markets. Other semiconductor variants for thin-film PV technology include copper indium diselenide, copper indium disulfide, copper indium aluminum diselenide, and cadmium telluride.

Some thin-film PV materials may be deposited either on rigid glass substrates, or on flexible substrates. Glass substrates are relatively inexpensive, generally have a coefficient of thermal expansion that is a relatively close match with the CIGS or other absorber layers, and allow for the use of vacuum deposition systems. However, when comparing technology options applicable during the deposition process, rigid substrates suffer from various shortcomings during processing, such as a need for substantial floor space for processing equipment and material storage, expensive and specialized equipment for heating glass uniformly to elevated temperatures at or near the glass annealing temperature, a high potential for substrate fracture with resultant yield loss, and higher heat capacity with resultant higher electricity cost for heating the glass. Furthermore, rigid substrates require increased shipping costs due to the weight and fragile nature of the glass. As a result, the use of glass substrates for the deposition of thin films may not be the best choice for low-cost, large-volume, high-yield, commercial manufacturing of multi-layer functional thin-film materials such as photovoltaics. Therefore, a need exists for improved methods and apparatus for depositing thin-film layers onto a non-rigid, continuous substrate.

### BRIEF DESCRIPTION OF THE DRAWINGS

FIG. 1 is a top view of a thin-film photovoltaic cell, according to aspects of the present disclosure.

FIG. 2 is a schematic side elevational view showing formation of a p-type semiconductor layer within a deposition chamber.

FIG. 3 is a schematic side elevational view showing interior portions of an apparatus for forming a p-type semiconductor layer in a multi-zone process.

FIG. 4 is a perspective view showing one of the zones of FIG. 3 in more detail.

FIG. 5 is a graph showing two different gallium to gallium+indium ratios as a function of depth within a semiconductor layer.

FIG. 6 is a graph showing the relationship between the composition of material within a pre-mixed source and the composition of vapor emitted by the source.

FIG. 7 is a perspective view of a vapor-mixing source, according to the present disclosure.

FIG. 8 is an overhead view of the heater plate and mixing manifold portion of the example apparatus shown in FIG. 7.

FIG. 9a is a flow chart showing exemplary steps in a first method of depositing gallium and indium on a substrate according to the teachings of the present disclosure.

FIG. 9b is a flow chart showing exemplary steps in a second method of depositing gallium and indium on a substrate according to the teachings of the present disclosure.

FIG. 10 is a schematic block diagram showing an apparatus constructed according to the present disclosure.

### DETAILED DESCRIPTION

### I. Introduction

Manufacture of flexible thin-film PV cells may proceed by a roll-to-roll process. As compared to rigid substrates, roll-to-roll processing of thin flexible substrates allows for the use of relatively compact, less expensive vacuum systems, and of some non-specialized equipment that already has been developed for other thin-film industries. Flexible substrate materials inherently have lower heat capacity than glass, so that the amount of energy required to elevate the temperature is minimized. They also exhibit a relatively high tolerance to rapid heating and cooling and to large thermal gradients, resulting in a low likelihood of fracture or failure during processing. Additionally, once active PV materials are deposited onto flexible substrate materials, the resulting unlaminated cells or strings of cells may be shipped to another facility for lamination and/or assembly into flexible or rigid solar modules. This strategic option both reduces the cost of shipping (due to the use of lightweight flexible substrates vs. glass), and enables the creation of partner-businesses for finishing and marketing PV modules throughout the world. Additional details relating to the composition and manufacture of thin-film PV cells of a type suitable for use with the presently disclosed method and apparatus may be found, for example, in U.S. Pat. No. 7,194,197, to Wendt et al., in patent application Ser. No. 12/424,497, filed Apr. 15, 2009, and in Provisional Patent Application Ser. No. 61/063,257, filed Jan. 31, 2008. These references are hereby incorporated into the present disclosure by reference for all purposes.

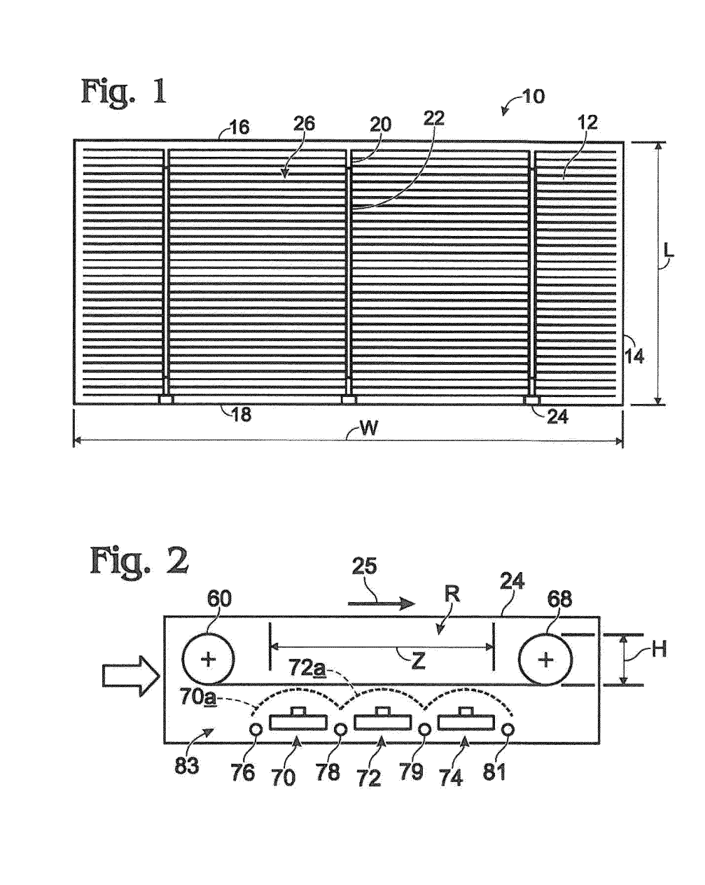

FIG. 1 shows a top view of a thin-film photovoltaic cell 10, in accordance with aspects of the present disclosure. Cell 10 is substantially planar, and typically rectangular as depicted in FIG. 1, although shapes other than rectangular may be more suitable for specific applications, such as for an odd-shaped rooftop or other surface. The cell has a top surface 12, a bottom surface 14 opposite the top surface, and dimensions including a length L, a width W, and a thickness. The length and width may be chosen for convenient application of the cells and/or for convenience during processing, and typically are in the range of a few centimeters (cm) to tens of cm. For example, the length may be approximately 100 millimeters (mm), and the width may be approximately 210 mm, although any other suitable dimensions may be chosen. The edges spanning the width of the cell may be characterized respectively as a leading edge 16 and a trailing edge 18. The total thickness of cell 10 depends on the particular layers chosen for the cell, and is typically dominated by the thickness of the underlying substrate of the cell. For example, a stainless steel substrate may have thickness on the order of 0.025 mm (25 microns), whereas all of the other layers of the cell may have a combined thickness on the order of 0.002 mm (2 microns) or less.

Cell 10 is created by starting with a flexible substrate, and then sequentially depositing multiple thin layers of different materials onto the substrate. This assembly may be accomplished through a roll-to-roll process whereby the substrate travels from a pay-out roll to a take-up roll, traveling through a series of deposition regions between the two rolls. The PV material then may be cut to cells of any desired size. The substrate material in a roll-to-roll process is generally thin, flexible, and can tolerate a relatively high-temperature environment. Suitable materials include, for example, a high temperature polymer such as polyimide, or a thin metal such as stainless steel or titanium, among others. Sequential layers typically are deposited onto the substrate in individual processing chambers by various processes such as sputtering, evaporation, vacuum deposition, chemical deposition, and/or printing. These layers may include a molybdenum (Mo) or chromium/molybdenum (Cr/Mo) back contact layer; an absorber layer of material such as copper indium diselenide, copper indium disulfide, copper indium aluminum diselenide, or copper indium gallium diselenide (GIGS); a buffer layer or layers such as a layer of cadmium sulfide (CdS); and a transparent conducting oxide (TCO) layer acting as the top electrode of the PV cell. In addition, a conductive current collection grid, usually constructed primarily from silver (Ag) or some other conductive metal, is typically applied over the TCO layer.

Although the precise thickness of each layer of a thin-film PV cell depends on the exact choice of materials and on the particular application process chosen for forming each layer, exemplary materials, thicknesses and methods of application of each layer described above are as follows, proceeding in typical order of application of each layer onto the substrate:

| Layer | Exemplary | Exemplary | Exemplary Method |
|---|---|---|---|
| Description | Material | Thickness | of Application |
| Substrate | Stainless steel | 25 μm | N/A (stock material) |
| Back contact | Mo | 320 nm | Sputtering |
| Absorber | CIGS | 1700 nm | Evaporation |
| Buffer | CdS | 80 nm | Chemical deposition |
| Front electrode | TCO | 250 nm | Sputtering |
| Collection grid | Ag | 40 μm | Printing |

The remainder of this disclosure focuses on various methods and apparatus for forming a semiconductor absorber layer on an underlying substrate web.

### II. Absorber Layer

This section describes various general considerations regarding formation of a thin-film absorber layer on a substrate web. The absorber layer typically is p-type semiconductor in the form of copper-indium-gallium-diselenide (CIGS) or its readily acceptable counterpart, copper-indium-diselenide (CIS). Other materials, such as copper indium disulfide or copper indium aluminum diselenide, also may be used. These different compositions, among others, can be used essentially interchangeably as an absorber layer in various embodiments of the present teachings, depending on the particular properties desired in the final product. For convenience and specificity, the remainder of this disclosure occasionally may refer to the absorber layer as a CIGS layer. However, it should be understood that some or all of the present teachings also may be applied to various other suitable absorber layer compositions.

FIG. 2 illustrates schematically a configuration for the inside of an absorber layer deposition chamber 24 according to one embodiment of the present teachings. As shown schematically in FIG. 2, the absorber layer is applied within the deposition chamber, and specifically within a deposition region R of the chamber, in a multi-step process. The deposition region, and typically the entire deposition chamber, are evacuated to near vacuum, typically to a pressure of approximately 700-2000 microtorr (μTorr). This background pressure typically is primarily supplied by selenium gas emitted into the deposition region by a selenium delivery system, resulting in deposition of selenium onto the web. The deposition of additional materials such as gallium, indium and copper generally may be described as a roll-to-roll, molten-liquid-to-vapor co-evaporation process.

The strip material, or substrate web, feeds in the direction of arrow 25 from a pay-out roll 60 to a downstream take-up roll 68 within chamber 24. As the strip material moves through chamber 24, the p-type absorber layer is formed on the bottom surface of the substrate web (as depicted in FIG. 2). A transport-guide structure (not shown) is employed between rolls 60, 68 in chamber 24 to support and guide the strip. The short, open arrow which appears at the left side of the block representation of chamber 24 in FIG. 2 symbolizes the hardware provided for the delivery of appropriate constituent substances to the interior of chamber 24.

Within chamber 24, and specifically within deposition region R, a molten-liquid-to-vapor co-evaporation process for establishing a p-type semiconductor layer is performed. Chamber 24 is designed specifically for the creation of a CIGS layer, as opposed, for example, to a CIS layer. Accordingly, structures 70, 72, 74, 76, 78, 79 and 81 function to generate vapors of copper (70), gallium (72), indium (74) and selenium (76, 78, 79, 81) for deposition onto the moving substrate web. Structures 70-81 form the bulk of the vapor-deposition-creating system, generally indicated at 83, of the present embodiment. The vapor deposition environment created in deposition region R may provide a continuum of evaporant fluxes. Within region R, effusion fluxes may be held approximately constant, and by translating the substrate web over the sources, the substrate may encounter a varying flux of material specifically designed to achieve optimum performance in the CIGS layer.

Blocks 70, 72 and 74, which relate to the vapor-delivery of copper, gallium, and indium, respectively, represent heated effusion sources for generating plumes of vapor derived from these three materials. Each of these effusion sources may include: (1) an outer thermal control shield; (2) a boat, reservoir, or crucible containing the associated molten copper, gallium, or indium; (3) a lid that covers the associated case and reservoir, and that contains one or more vapor-ejection nozzles (or effusion ports) per crucible to assist in creating vapor plumes; and (4) a specially designed and placed heater located near the effusion ports, or in some embodiments formed integrally with the ports.

Structures 76, 78, 79 and 81 represent portions of a selenium delivery system that creates a background selenium gas pressure in some or all parts of the deposition region. A selenium delivery system may deliver selenium directly through one or more orifices in a local Se source. Alternatively, in the embodiment of FIG. 2, circles 76, 78, 79, 81 represent end views of plural, laterally spaced, generally parallel elongate sparger tubes (or fingers) that form part of a manifold that supplies, to the deposition environment within chamber 24, a relatively evenly volumetrically dispersed selenium vapor. Each tube has one or more linearly spaced outlet orifices, each orifice having a diameter of approximately one millimeter (1.0 mm). The delivered selenium vapor may be derived from a single pool, site, or reservoir of selenium, which typically vaporizes within the reservoir through sublimation. The selenium delivery system may be configured to provide any suitable selenium pressure within the deposition region, which in most embodiments will fall within the range of 0.7-2.0 millitorr.

The processing rate using a roll-to-roll deposition approach is limited only by the web translation rate through the deposition region, and by the web width. The web translation rate is set by the minimum time required for sufficient film deposition, which is determined by the details of the reactions that occur inside the deposition region. The maximum web width is limited by the requirement of sufficiently uniform composition and thickness across the width and, as a practical matter, also may be limited by the availability of sufficiently wide rolls of suitable substrate material, such as 25 μm-thick stainless steel. Some vacuum coating techniques, including evaporative techniques used for CIGS deposition and described in the present disclosure, rely on evaporation sources that use arrays of orifices, or effusion ports, arranged to provide sufficiently uniform deposition. Deposition uniformity across the width of the web (concurrent with sufficient material deposition) can be achieved if the effusion ports are spaced across the web width, and if the mass flow of each effusion port is well-controlled.

### III. Multi-Zone Deposition

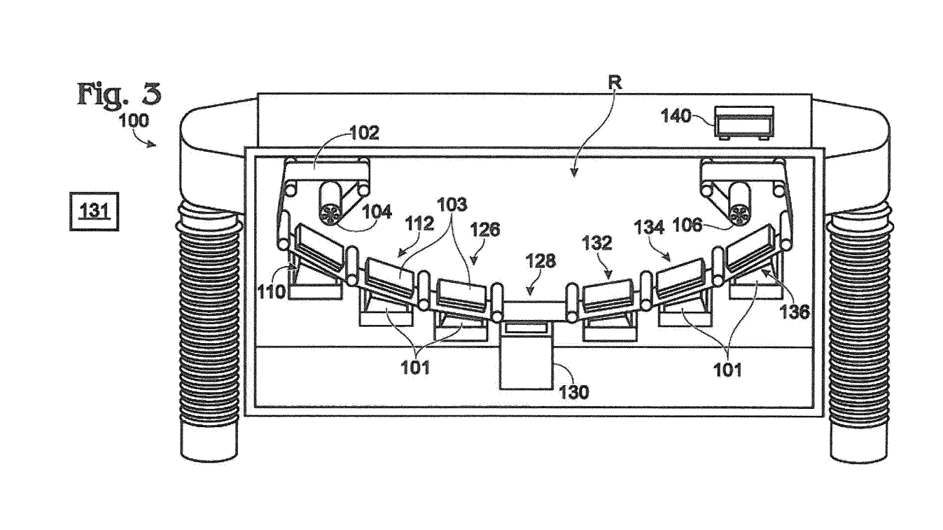

This section relates to systems and methods for depositing a thin-film p-type semiconductor layer onto a substrate in a specific exemplary multi-zone deposition process. As described previously and depicted schematically in FIG. 2, a semiconductor layer generally may be deposited sequentially, by applying various components of the layer separately and/or in overlapping combinations. FIG. 3 is a more detailed schematic side elevational view of an apparatus for performing such a sequential deposition process. As FIG. 3 depicts, the deposition may be accomplished in a seven-zone procedure, wherein six of the seven zones are used to deposit portions of the semiconductor layer, and a seventh intermediate zone is used to monitor one or more properties of the previously deposited layers. The seven-zone procedure depicted in FIG. 3 and described herein is exemplary, and it should be appreciated that an effective p-type semiconductor layer may be deposited in a similar procedure having greater or fewer than seven zones.

In the exemplary procedure of FIG. 3, as in the more general procedure depicted in FIG. 2, deposition of the semiconductor layer occurs inside a deposition region R of an absorber layer deposition chamber 100 that has been evacuated to near vacuum, typically to a pressure of approximately 0.7-2.0 millitorr (700-2000 μTorr) that is provided by selenium gas. Also as in the general embodiment of FIG. 2, deposition in the embodiment of FIG. 3 proceeds via a roll-to-roll, molten-liquid-to-vapor co-evaporation process, wherein a substrate web 102 is transported through the deposition region from a pay-out roll 104 to a take-up roll 106, with the pay-out roll and the take-up roll both located within deposition chamber 100. Alternatively, the pay-out and take-up rolls may be disposed outside of, but in close proximity to, the deposition chamber. Substrate heaters 103 may be positioned at one or more locations of the processing path to heat substrate web 102.

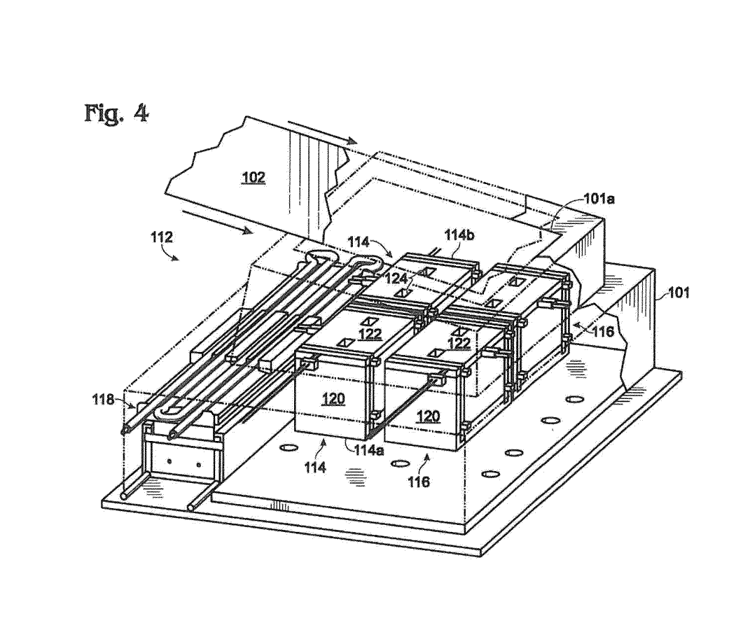

Each of the six deposition zones described in this section may have a similar basic structure but may vary as to number, deposition material and location within the zone, of material sources. Each zone may include at least two material sources, for example the material sources shown in FIG. 4, each configured to emit plumes of molecules to be deposited on the moving substrate web 102, which passes above and at a distance from the sources. Two of the at least two material sources may be disposed substantially symmetrically across the transverse dimension or width of the web and may contain the same deposition material to be deposited uniformly on the moving substrate web 102.

In some zones, such as in the zone depicted in FIG. 4 and described in more detail below, two separate deposition materials may be deposited onto the web. In such cases, four sources may be provided, a first set of two sources disposed substantially symmetrically across the transverse dimension or width of the web containing a first deposition material and a second set of two sources disposed substantially symmetrically across the transverse dimension or width of the web containing a second deposition material. Each set of two sources may be configured to deposit a different material across the entire width of the web. In other zones, where only a single material is deposited onto the web, a single set of two sources may be provided and configured to deposit one material across the web.

Each deposition zone may be enclosed within a separate solid enclosure 101. Generally, each enclosure 101 may surround the associated deposition zone substantially completely, except for an aperture in the top portion of the enclosure over which the moving substrate web passes. This allows separation of the deposition zones from each other, providing the best possible control over parameters such as temperature and selenium pressure within each zone.

The exemplary chamber 100 of FIG. 3 is designed specifically for the creation of a CIGS layer by passing the substrate web through seven separate zones, including at least one or more deposition zones, within deposition region R, resulting in a CIGS layer of composite thickness between a few hundred and a few thousand nanometers. Provided below is a sequential description of each of the seven zones (110, 112, 126, 128, 132, 134, and 136) shown in FIG. 3.

Specifically, first zone 110 may be configured to deposit a layer of sodium fluoride (NaFl) onto the web. The presence of sodium is believed to improve p-type carrier concentration by compensating for defects in one or more of the subsequently deposited CIGS layers, and thus to improve the overall efficiency of the PV cell. An initial layer of NaFl has been found to be optimal. Alternatively, potassium (K) or lithium (Li) may serve a similar purpose as sodium. Furthermore, other compounds aside from NaFl, such as sodium selenide (Na₂Se₂), sodium selenite (Na₂SeO₃), sodium selenate (Na₂O₄Se), or other similar compounds incorporating potassium and/or lithium, also may be suitable for improving p-type carrier concentration.

Second zone 112, which is shown in isolation in FIG. 4, may be configured to deposit a layer of gallium indium (GI) onto the web (or more precisely, onto the previously deposited layer of NaFl). Second zone 112 may include two gallium sources 114 disposed substantially symmetrically across the transverse dimension of the web and two indium sources 116 similarly disposed substantially symmetrically across the transverse dimension of the web. Also depicted in second zone 112 of FIG. 4 is a selenium (Se) source, generally indicated at 118. Selenium source 118 is configured to provide selenium gas to second zone 112. Providing a background of selenium gas results in deposition on the substrate web of selenium along with the GI layer.

GI (more specifically GI selenide) may be deposited through the nearly simultaneous—but separate—deposition of gallium and indium onto the same portion of the moving web. As indicated in FIG. 4, however, gallium sources 114 may be located slightly before indium sources 116 within the second zone 112, so that a small amount of gallium is deposited onto the web prior to deposition of any indium. Because gallium adheres better to the underlying web and to the previously deposited NaFl molecules, this arrangement results in better overall adhesion of the GI layer deposited in the second zone.

Selenium source 118 is configured to provide selenium gas to second zone 112, and similar selenium sources may also be located in the third, fifth, sixth and/or seventh zones within chamber 100 to provide selenium gas to the third, fifth, sixth and/or seventh zones within chamber 100, up to a pressure in the range of approximately 700-2000 μTorr. Each selenium source in a zone may be independently monitored and controlled. Providing a background of selenium gas results in deposition of selenium along with the other source materials, such as GI, such that the deposited layer may comprise indium-gallium selenide, gallium selenide or gallium-rich indium-gallium selenide.

As shown in more detail in FIG. 4, each of the two gallium sources 114 and each of the two indium sources 116 within second zone 112, and more generally each material source in any of the zones of chamber 100, may generally include a crucible or body portion 120, and a lid 122 containing one or more effusion ports 124.

Each deposition zone may itself be enclosed within a separate solid enclosure 101. Generally, each enclosure 101 may surround the associated deposition zone, for example second zone 112, substantially completely, except for an aperture 101a in the top portion of enclosure 101, over which the moving substrate web passes. This allows separation of the deposition zones from each other, providing the best possible control over parameters such as temperature and selenium pressure within each zone. Aperture 101a in the top portion of enclosure 101 may have a width that is substantially the same as the width of substrate web 102.

A deposition material is liquefied or otherwise disposed within the body portion 120 of a given source, and emitted at a controlled temperature in plumes of evaporated material through effusion ports 124. As described previously, because the angular flux of material emitted from an effusion port 124 with a particular geometry is a function primarily of temperature of the port and/or deposition material, this allows for control over the thickness and uniformity of the deposited layers created by the vapor plumes.

As shown in FIG. 3, third deposition zone 126 may be configured to deposit a layer of copper (Cu) onto the moving web. Third deposition zone 126 may include two material sources, which are structurally similar or identical in construction to the gallium and indium sources 114 and 116 described with reference to FIG. 4. Specifically, third deposition zone 126 may include two material sources, containing the deposition material copper, disposed substantially symmetrically across the transverse dimension or width W of the web. The two sources may generally include at least a body portion, and a lid containing one or more effusion ports. Third deposition zone 126 may also include a selenium source.

Sources of copper material may disposed within the third zone 126 relatively close to the entrant side of the substrate web 102 into the third zone 126, but alternatively may be disposed more toward the egress side of the third zone 126 with similar effect. However, by providing the copper sources relatively close to the entrant side of the third zone 126, the copper atoms have slightly more time to diffuse through the underlying layers prior to deposition of subsequent layers, and this may lead to preferable electronic properties of the final CIGS layer.

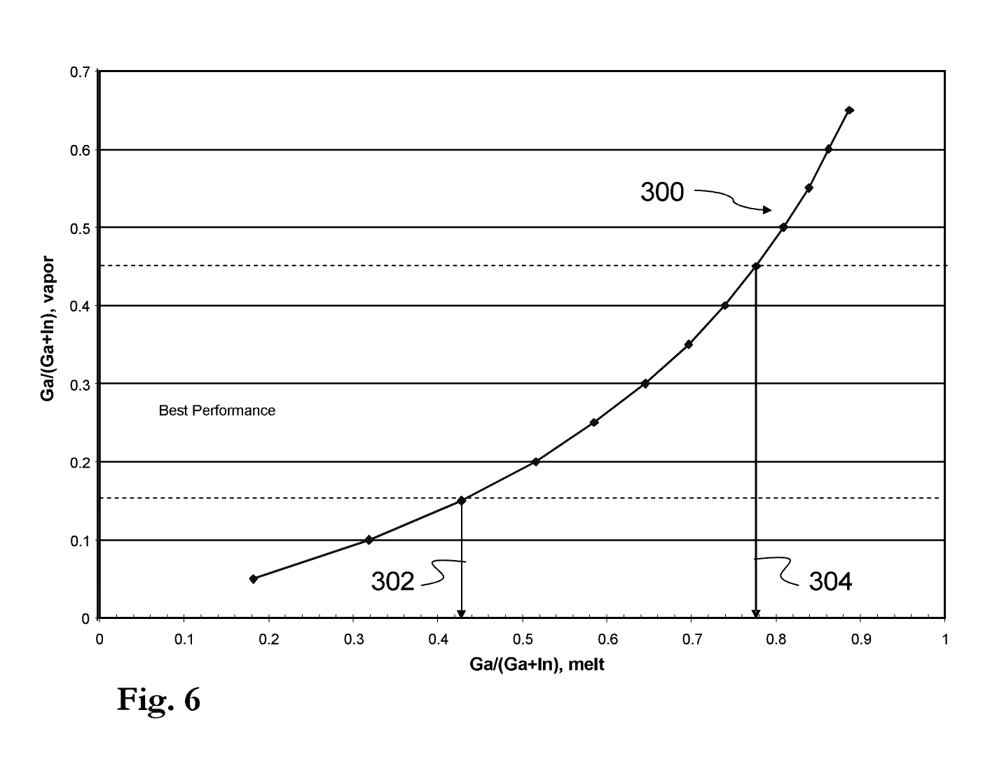

Fourth zone 128 may be configured as a sensing zone, in which one or more sensors, generally indicated at 130, monitor the thickness, uniformity, or other properties of some or all of the previously deposited material layers. Typically, such sensors may be used to monitor and control the effective thickness of the previously deposited copper, indium and gallium on the web, by adjusting the temperature of the appropriate deposition sources in the downstream zones and/or the upstream zones in response to variations in detected thickness. To monitor properties of the web across its entire width, two or more sensors may be used, corresponding to the two or more sources of each applied material that span the width of the web disposed substantially symmetrically across the transverse dimension of the web. Fourth zone 128 is described in more detail below with reference to FIG. 6.

Fifth zone 132 may be configured to deposit a second layer of copper, which may have somewhat lesser thickness than the copper layer deposited in third zone 126, from a pair of sources disposed substantially symmetrically across the transverse dimension of the web. Similar to the copper sources described in third zone 126, two copper sources within fifth zone 132 may be configured to emit copper plumes from multiple effusion ports spanning the width of the substrate web. Furthermore, the copper sources may be disposed on the entrant side of the fifth zone 132 to allow relatively more time between copper deposition and subsequent layer deposition. Fifth zone 132 may also include a selenium source.

Sixth zone 134 may be configured to deposit a second layer of gallium-indium onto the web. In construction, sixth zone 134 may be similar to second zone 112. The thickness of the gallium-indium layer deposited in sixth zone 134 may be small relative to the thickness of the GI layer deposited in second zone 112. In sixth zone 134, gallium and indium may be emitted at somewhat lesser effusion temperatures relative to the effusion temperatures of the gallium and indium emitted in second zone 112. These relatively lower temperatures result in lower effusion rates, and thus to a relatively thinner layer of deposited material. Such relatively low effusion rates may allow fine control over ratios such as the copper to gallium+indium ratio (Cu:Ga+In) and the gallium to gallium+indium ratio (Ga:Ga+In) near the p-n junction, each of which can affect the electronic properties of the resulting PV cell. As in the second zone 112, gallium may be emitted slightly earlier along the web path than indium, to promote better adhesion to the underlying layers of molecules.

Seventh zone 136 may be similar in construction to one or both of second zone 112 and sixth zone 134 and may be configured to deposit a third slow-growth, high quality layer of gallium-indium (GI) onto the substrate web. In some embodiments, this final deposition zone and/or GI layer may be omitted from the deposition process, or a layer of indium alone may be deposited in seventh zone 136. As in sixth zone 134, application of a relatively thin, carefully controlled layer of gallium and/or indium allows control over ratios such as (Cu:Ga+In) and (Ga:Ga+In) near the p-n junction. This may have a beneficial impact on the efficiency of the cell by, for example, allowing fine-tuning of the electronic band gap throughout the thickness of the CIGS layer. Furthermore, the final layer of GI is the last layer applied to complete formation of the p-type CIGS semiconductor, and it has been found beneficial to form a thin layer of GI having a relatively low defect density adjacent to the p-n junction that will be subsequently formed upon further application of an n-type semiconductor layer on top of the CIGS layer.

As shown in FIG. 4, second zone 112 may include two gallium sources 114 disposed substantially symmetrically across the transverse dimension of the web, and two indium sources 116 disposed substantially symmetrically across the transverse dimension of the web. In other words, two sources containing identical deposition material may span the width of substrate web 102, to provide a layer of material across the entire width of the web having a uniform thickness. The operation, including effusion rate and/or temperature of each source in a zone may be controlled and/or monitored independently of the second source in the zone having the same deposition material. For example, each gallium source 114a may include a heating element that is adjustable independent of a heating element included in the second gallium source 114b.

This basic structure, with at least two independently operable heated sources containing the same deposition material spanning the web width, may be common to each of the zones of chamber 100 in which material is deposited onto the web (deposition zones 110, 112, 126, 132, 134 and 136). By providing two independent sources of material disposed substantially symmetrically across the width of the web, the thickness of each deposited material may be independently monitored on each side of the web, and the temperature of each source may be independently adjusted in response. This allows a wider web to be used, leading to a corresponding gain in processing speed per unit area, without compromising material thickness uniformity.

### IV. Optimizing Layer Composition with Mixed Sources

As noted above, ratios such as the copper to gallium+indium ratio and the gallium to gallium+indium ratio (“GGI”) in the CIGS layer can affect the electronic properties of the resulting PV cell. Accordingly, achieving control over these ratios is desirable in a CIGS deposition system.

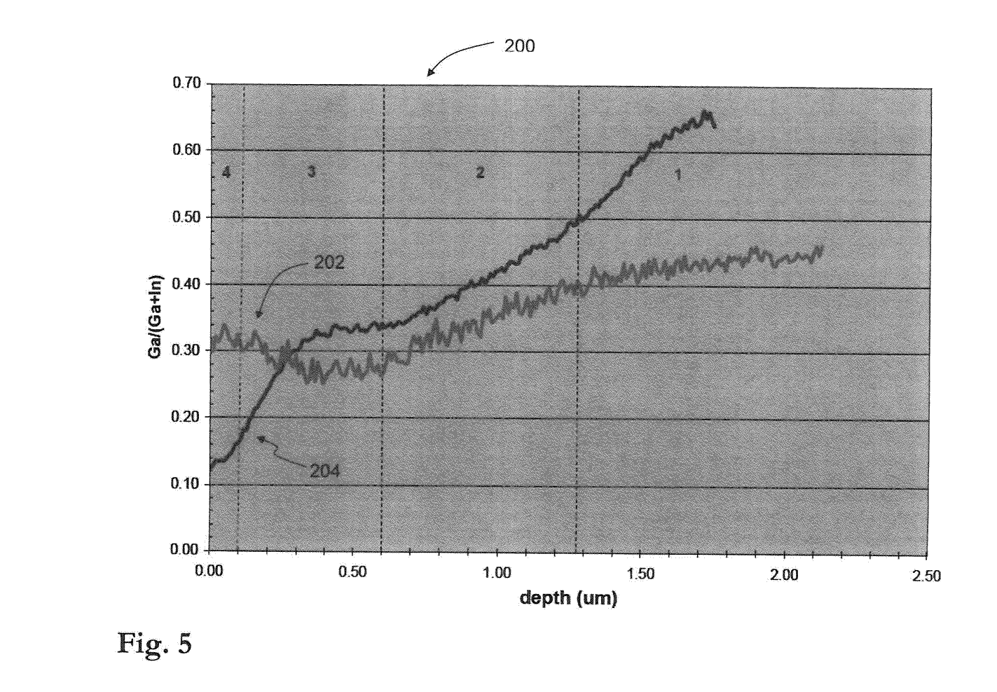

More specifically, the GGI ratio throughout the CIGS film thickness is a strong determinant of solar cell efficiency. FIG. 5 is a graph, generally indicated at 200, depicting at 202 a generally desirable GGI profile as a function of depth within the CIGS layer, and depicting at 204 a less desirable GGI profile that is typical of some currently manufactured thin-film PV cells. The GGI ratio within the different depth regions (labeled 1-4) affects the electrical characteristics of the solar cell in different ways. The GGI profile in regions 1 and 2 primarily controls the short circuit current of the corresponding cell, and the GGI profile in regions 3 and 4 primarily controls the open-circuit voltage of the corresponding cell. Some specific features of a GGI profile believed to be desirable are:

achieving a GGI ratio between 0.25 and 0.35 in region 2;

a GGI “well” 0.4 to 0.5 μm below the surface of the CIGS layer;

a mild slope towards the back of the CIGS coating (i.e., in regions 3 and 4);

a maximum GGI ratio of between 0.40 and 0.50; and

a modest decline in the GGI ratio in region 4.

As described previously, one method of attempting to control the GGI ratio as a function of depth is to use independently controllable gallium and indium sources. According to the teachings of this section, another method is to mix gallium and indium inside a single source (or inside multiple sources), which may preferably be disposed in the last deposition zones through which a moving substrate web passes (zones 6 and/or 7 as described in the previous section). It is preferable to have finer control of the deposition of gallium and indium in these later zones because, as the thin film deposition process nears its end, less time is available for solid state diffusion to occur after layers are deposited. Thus, controlled mixing of the source materials prior to deposition is desirable, especially in these final zones.

In a mixed source, at least two possible mixing methods may be used. In a first method, indium and gallium are mixed prior to evaporation, forming a continuous solution in the melt. This first method will generally be referred to as “pre-mixing.” In a second method, separate crucibles containing gallium or indium may be used in a single source, with resulting indium and gallium vapors being mixed in a manifold prior to exiting through the source's effusion port(s). This second method will generally be referred to as “vapor-mixing.” In either method, the vapor pressures of the individual elements (and their evaporation behavior) are largely preserved in the resulting alloy.

When a mixed source is used, indium and gallium vapors leaving the source are generally well mixed throughout the entire deposition zone. As a result, mixtures can be accomplished which result in a nearly constant GGI ratio over substrate web lengths greater than 500 meters, and process control can be maintained. In addition, using mixed mixing indium and gallium sources yields flatter GGI profiles through the CIGS coating and more uniform profiles across the web width. In particular, a GGI ratio between 0.25 and 0.35 at the film surface typically can be achieved by this approach. To facilitate uniformity of the GGI ratio, multiple sources mixing indium and gallium may be disposed across the width of the substrate web, as depicted generally in FIG. 4.

In addition to a single mixed indium gallium source, a plurality of mixed sources or sources containing only indium or gallium may be added to the deposition system, and may result in even finer control of the GGI profile by adding another degree of freedom. Control over the GGI ratio may be more straightforward if only one of the sources is a mixed source. Accordingly, the following configurations of mixed and/or single material sources may be used in the terminal CIGS deposition zones:

a. Ga, (In,Ga)

b. (In, Ga), In

c. (In,Ga), (In,Ga)

d. (In, Ga) only

When multiple mixed sources are used (as in option (c) above), the first source the substrate is exposed to will typically have a smaller GGI ratio than the second source.

Another possible implementation of a single mixed indium and gallium source is earlier in the deposition process, i.e. not necessarily in the terminal deposition zones.

This may be useful because the GGI profile near the back contact (regions 3 and 4 in FIG. 5) is important for efficient carrier (electric current) collection. Specifically, a relatively gradual slope in the GGI ratio can be obtained in regions 3 and 4 by the following configurations of a first source and a second source (relative to the moving web) in an early deposition zone:

a. (In,Ga), In

b. (In, Ga) only

In the case of a single mixed indium gallium source at the beginning of CIGS deposition, reaction kinetics may lead to a natural decreasing gradient in the GGI ratio, with a higher ratio near the back contact region, as desired.

When using one or more mixed indium gallium sources, it remains important to precisely control the amount of source material deposited on the substrate web. In a first, or pre-mixing option, this control may be generally accomplished by controlling the ratio of the gallium and indium used in the mixture. For simplicity, consider the case of only a single pre-mixed indium gallium source installed in the final CIGS deposition zone to supply all indium and gallium necessary to complete the final stage of the CIGS deposition process. The ratio of indium to gallium (and thus the GGI ratio) that effuses from the mixed source is determined by the charge mixture and the temperature at which the source is operated. However, the source temperature cannot affect the ratio independent of the total amount of indium and gallium effusing. Furthermore, the charge mixture typically cannot be modified once the system is evacuated and the deposition process is initiated. Therefore, it is desirable to know the relationships between the melt composition within a mixed source, the composition of the mixed vapor effused by the source, and the composition of the mixed film that actually adheres to the substrate.

FIG. 6 is a graph showing the experimentally determined relationship, generally indicated at 300, between the pre-mixed GGI ratio in the source (i.e. the “melt”) and the GGI ratio in the vapor emitted by the source under a particular set of operating conditions. This relationship, or the equivalent for different operating conditions, can be used to determine the melt composition for a particular desired vapor composition. In some situations, the vapor composition may be similar or nearly identical to the resulting film composition deposited on the substrate. In other cases, however, there may be a slight loss of indium deposited on the substrate (typically 5%-10%), in which case it is desirable to achieve a vapor composition that has a slightly lower GGI ratio (i.e. that includes a slightly higher fraction of indium) than the desired ratio to be deposited on the substrate.

For an efficient solar cell, there is a range of acceptable GGI ratios deposited during the final stage of the CIGS deposition process. This preferred range is approximately 10% to 45%, as indicated by lines 302 and 304 in FIG. 6, respectively. If the GGI ratio can be controlled within that range due to the charge mixture, and the final film Cu/(Ga+In) ratio is also controlled within a desired range, then solar material having desirable properties generally can be produced. More specifically, tests have shown that cell efficiency approaching 13% can be achieved, which is similar to the highest efficiency achieved with separate indium and gallium sources.

As described above, in a process using a pre-mixed indium gallium source, the relative amounts of indium and gallium are based on how the source was charged. Therefore, the optimal control strategy with a pre-mixed source is to charge the source precisely with desired masses of indium and gallium, and to use the total number of molecules of indium and gallium deposited onto the substrate web from the mixed source as the process control variable for the effusion from that source.

In the second, or vapor-mixing option, where gallium and indium are located in separate crucibles within the source, gallium and indium vapors are mixed in a manifold or chamber and the ratio of gallium and indium may be controlled using independent heating for each crucible. This method has resulted in even finer control of the GGI ratio, due to different evaporation characteristics of each source material. Use of a mixing manifold allows better outcome control and more complete mixing of gallium and indium than does use of non-mixed sources where the process must rely on plume overlap and diffusion in the applied layers.

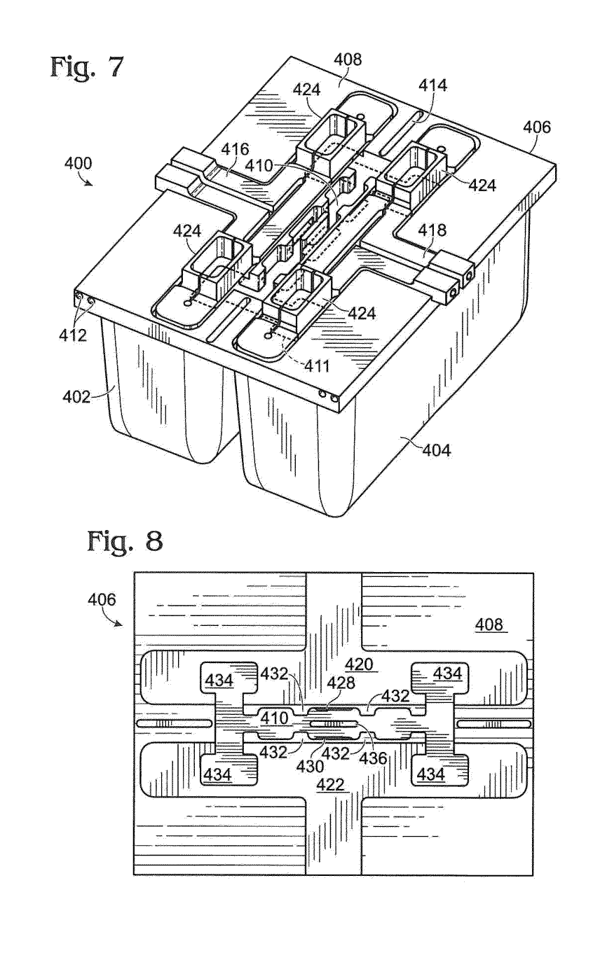

FIG. 7 shows an example of a multi-crucible vapor-mixing source according to the present teachings, generally indicated at 400. First crucible 402 contains a first source material. For example, first crucible 402 may contain indium. Second crucible 404 contains a second source material. For example, second crucible 404 may contain gallium. First crucible 402 and second crucible 404 may be rigidly connected to integrated assembly 406. Integrated assembly 406 may include heater plate 408 and manifold chamber 410. The general outline of the floor of manifold chamber 410 is shown in FIG. 7 by dashed line 411.

Heater plate 408 may be substantially rectangular and planar, with suitable recesses and openings further described below. Heater plate 408 may also include one or more bores 412 for suitably housing measuring devices such as thermocouples. Additionally, heater plate 408 may include thermal breaks, such as thermal break 414, which are narrow slots milled out of the solid material of heater plate 408. Thermal break 414 is appropriately sized to minimize thermal conduction from one side of heater plate 408 to the other without significant loss of structural strength, thus facilitating independent temperature control for each crucible.

First heating element 416 may be located within first recess 420 and second heating element 418 may be located within second recess 422 in heater plate 408. First heating element 416 and second heating element 418 may be single-piece heating elements which provide heating to vaporize source material in first crucible 402 and second crucible 404, respectively. First heating element 416 and second heating element 418 may also form one or more nozzles 424 through which vaporized source material may flow. Because nozzles 424 are formed by first heating element 416 and second heating element 418, heating of the vapor may be maintained until the vapor exits vapor-mixing source 400 completely. Examples of integrated heater/nozzle configurations are described in U.S. patent application Ser. No. 12/424,497, filed Apr. 15, 2009 which is incorporated herein by reference.

Vapor-mixing source 400 also includes sealing and thermal insulation layer 426 (not pictured), which may be configured to completely cover integrated assembly 406 with the exception of the effusion ports, or outlets, of nozzles 424 and any other openings required to allow access for devices such as instrument cables, electrical connections, and structural support members. Sealing and thermal insulation layer 426 may be any suitable material configured to provide thermal insulation and to substantially seal manifold chamber 410. Typically, a top seal is created using flexible grafoil (a carbon-based sheet-like material also used for high temperature gasket applications). The grafoil is die-cut to fit the top of heater plate 408, with cut-outs for nozzles 424. Layers of grafelt (a carbon-based fibrous high temperature thermal insulation) are then typically stacked to a suitable height, and a final layer of grafoil may be utilized to provide containment. The resulting stack of grafoil, grafelt, heating elements, integrated assembly 406, and crucibles may be clamped or otherwise connected together to maintain seals at all mating surfaces. Sealing and thermal insulation layer 426 may have any appropriate thickness such that suitable thermal insulation is provided without impeding vapor flow from the effusion ports of nozzles 424.

FIG. 8 shows an overhead view of integrated assembly 406, including heater plate 408 and manifold chamber 410. Heater plate 408 may include first recess 420 and second recess 422 as previously described. As shown in FIG. 8, manifold chamber 410 may be further recessed below the planes of heater plate 408 and first recess 420 and second recess 422. Manifold chamber 410 may include a first vapor opening 428 which creates a passage from first crucible 402, and a second vapor opening 430 which creates a passage from second crucible 404. Manifold chamber 410 may be any suitable size and shape to provide adequate mixing of vapors from the two crucibles prior to exiting through nozzles 424. For example, as shown in FIG. 8, manifold chamber 410 may be configured as an elongate compartment with necked passages created by a plurality of protrusions 432 and terminating in one or more exit cavities 434 situated below nozzles 424. Mixing manifold 410 may also include one or more barriers, such as barrier 436, which serve to further direct vapor flow and facilitate mixing. First heating element 416, second heating element 418, and thermal insulation layer 426 are not pictured in FIG. 8.

As depicted in FIG. 3, according to the present teachings a monitoring station 130 near a mid-point of the CIGS deposition system and/or another monitoring station 140 just prior to take-up roller 106 may be used to monitor one or more properties of the deposited CIGS layers. Each monitoring station may, for example, include two sensors provided across the width of the web, corresponding to two sources of material that are disposed substantially symmetrically across the width of the web in each deposition zone. Monitoring station 130 may monitor a property of the gallium-indium and copper material layers deposited in zones 110, 112 and/or 126, while monitoring station 140 cooperatively monitors one or more properties of the copper and gallium-indium material layers deposited in zones 132, 134 and/or 136.

Exemplary types of sensors suitable for use in monitoring stations 130 and 140 may include one or more of X-Ray Florescence (XRF), Atomic Absorption Spectroscopy (AAS), Parallel Diffraction Spectroscopic Ellipsometry (PDSE), IR reflectometry, Electron Impact Emission Spectroscopy (EIES), in-situ x-ray diffraction (XRD) both glancing angle and conventional, in-situ time-resolved photoluminescence (TRPL), in-situ spectroscopic reflectometry, in-situ Kelvin Probe for surface potential, and in-situ monitoring of emissivity for process endpoint detection. One or more computers (not shown) may be configured to analyze data from the monitoring station to monitor a property, such as thickness, of deposited layers, and subsequently to adjust the effusion rates and/or temperatures of a corresponding material source or crucible.

When mixed indium and gallium sources are used, the computer(s) used in conjunction with the monitoring stations may be configured to convert the measured thicknesses of indium and gallium to a total number of molecules deposited per unit area (e.g., using the density and molecular weight of gallium and indium). Determining the total amount of deposited material in this manner allows the deposited GGI ratio to be determined. Accurate control of the mixed source then may be attained by providing temperature adjustments to the mixed source(s) in response to the measured ratio.

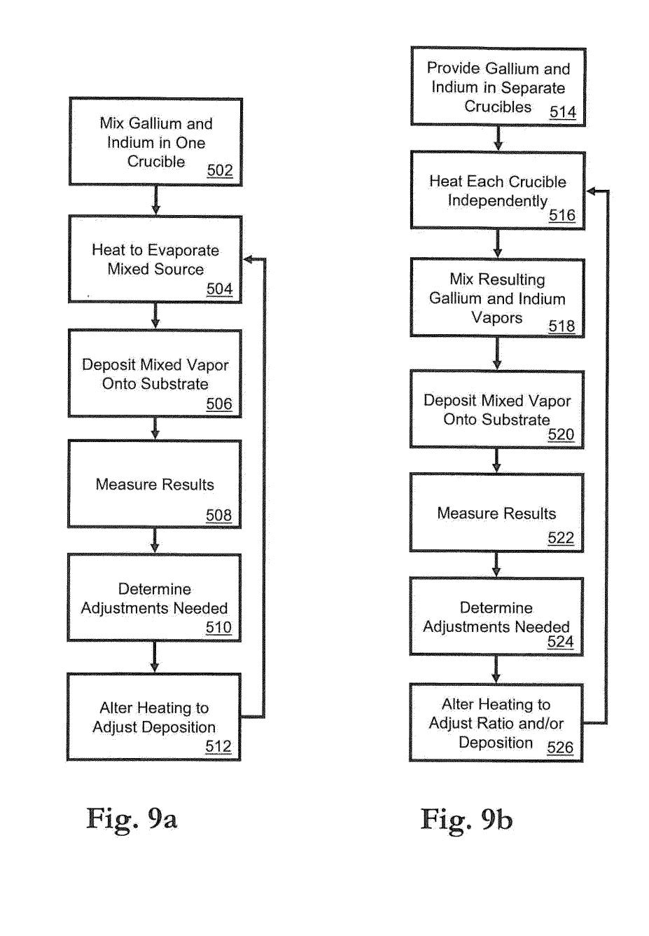

FIG. 9a shows a flow chart depicting an exemplary method for depositing a gallium and indium layer according to the pre-mixing method of the current teachings. In a first step 502, gallium and indium may be mixed in a single crucible or container. Exact proportions of gallium and indium may be utilized, with a preferred ratio in the range previously discussed, and thoroughly mixed by any suitable means. For example, proper quantities of gallium and indium, in solid shot or bead form, may be weighed into a container and stirred by hand with a small rod made of an inert material. T typically, the resulting eutectic mixture will exist in a liquid or semi-liquid state at room temperature. In step 504, the crucible may be heated to evaporate the mixed source material. Heating may be accomplished by any suitable method, including one or more electrical heating elements. As previously described and shown in FIG. 6, the vapor composition will retain a GGI ratio that is predictable given the ratio in the melt. In step 506, the vapor may be deposited onto a suitable substrate. This may be accomplished using a process already described, wherein a moving substrate web transported in roll-to-roll fashion passes over the source, and a layer of mixed gallium and indium vapor is deposited. Thickness of the deposited layer in this step may be substantially controlled by speed of web transport and heating of source material. In step 508, the deposited layer may be measured to determine whether desirable characteristics have been attained or maintained, whether adjustments have been successful, or whether the process is properly in control. This measurement may be accomplished, for example, at a suitable monitoring station utilizing instruments as previously described. In step 510, the results of measurement in step 508 may be analyzed by a processor configured to determine the characteristics of the deposited layer(s), to compare those characteristics to desired values, and to provide an output signal to cause adjustments calculated to bring the characteristics of the deposited layer(s) within desired parameters. This output signal may include automatic adjustment of heating, web transport speed, and/or human-readable displays or alarms. In step 512, the heating of the source materials may be adjusted to bring the characteristics of the deposited layer(s) within desired parameters. Use of one or more non-mixed gallium or indium sources may be employed such that this adjustment of heating of the source materials may include altering the temperature of one or more non-mixed sources instead of or in addition to the mixed sources.

FIG. 9b shows a flow chart depicting an exemplary method for depositing a gallium and indium layer according to the vapor-mixing method of the current teachings. In a first step 514, gallium and indium may be provided in separate crucibles or containers. In step 516, each crucible may be heated to evaporate the source material. Heating may be accomplished by any suitable method, including one or more electrical heating elements configured to heat the crucibles together or independently. Independent heating of each crucible is preferred, as it results in finer adjustment and control of the resulting vapor composition. In step 518, the resulting indium and gallium vapors may be combined in a suitable chamber configured to facilitate mixing of the vapors. Following this mixing, in step 520 the mixed vapor may be deposited onto a suitable substrate. As before, this may be accomplished using a process already described, wherein a moving substrate web transported in roll-to-roll fashion passes over a source, and a layer of mixed gallium and indium vapor is deposited. Thickness of the deposited layer in this step may be substantially controlled by speed of web transport and heating of source material, and GGI ratio may be controlled by adjustment of each crucible's temperature and evaporation rate. In step 522, the deposited layer may be measured to determine whether desirable characteristics have been attained or maintained, whether adjustments have been successful, or whether the process is properly in control. This measurement may be accomplished, for example, at a suitable monitoring station utilizing instruments as previously described. In step 524, the results of measurement in step 522 may be analyzed by any processor configured to determine the characteristics of the deposited layer(s), to compare those characteristics to desired values, and to provide an output signal to cause adjustments calculated to bring the characteristics of the deposited layer(s) within desired parameters. This output signal may include automatic adjustment of heating, web transport speed, and/or human-readable displays, alarms, and/or warnings. In step 526, the heating of the source materials may be adjusted to bring the characteristics of the deposited layer(s) within desired parameters. Use of one or more non-mixed gallium or indium sources may be employed such that this adjustment of heating of the source materials may include altering the temperature of one or more non-mixed sources instead of or in addition to the mixed sources.

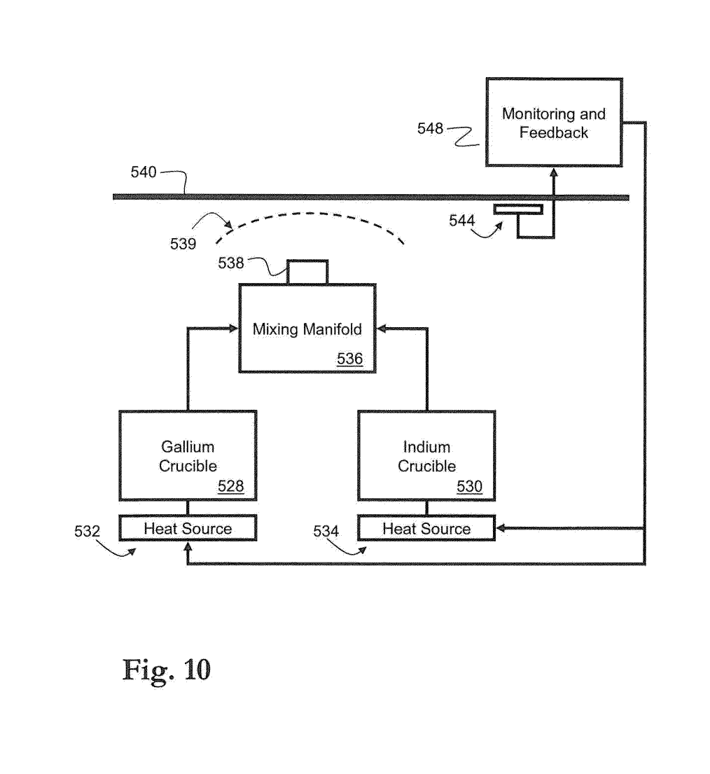

FIG. 10 shows a schematic block diagram of an apparatus for vapor-mixing, constructed according to principals described above. Gallium and indium are contained in gallium crucible 528 and indium crucible 530, respectively. For simplicity, only one of each type of crucible is shown. Any number or combination of said crucibles may be utilized. In thermal communication with each crucible is a heat source, shown at 532 and 534 in FIG. 10. In a preferred embodiment, a heat source is located above each crucible (rather than below, as pictured in FIG. 10), for example as part of a lid assembly or upper plate. Heated vapors from gallium crucible 528 and indium crucible 530 may be directed to a mixing manifold 536. Mixing manifold 536 may include any suitable structure configured to facilitate mixing of the indium and gallium vapors. For example, mixing manifold 536 may include structures such as necked chambers, protrusions, baffles, barriers, tortuous pathways, rotating vanes, and/or any other such devices to break up laminar flow and facilitate vapor combination. Mixing manifold 536 may also be heated, and a plurality of mixing manifolds may be utilized. After mixing, the combined gallium and indium vapor may be directed toward the surface of a passing substrate 540 by way of nozzle 538. Nozzle 538 may be any suitable structure configured to direct the flow of the mixed gallium and indium vapor. For example, nozzle 538 may be a protrusion with an oval- or rectangular-shaped opening located above mixing manifold 536. Nozzle 538 may be oriented such that its longitudinal axis is perpendicular or orthogonal to the plane of substrate 540. Alternatively, nozzle 538 may be angled for directional or structural considerations or in some applications, nozzle 538 may have an effective height of zero, comprising a mere hole or effusion port in a source apparatus. Any suitable number of nozzles such as nozzle 538 may be utilized. In an example embodiment previously described and shown in FIG. 7, nozzles such as nozzle 538 may be formed as part of one or more heating elements. Among other considerations, this configuration enables heating of the combined vapor until the moment it leaves the source, reducing or eliminating condensation of the vapor in the nozzle area. The combined vapor exits via the opening or effusion port in nozzle 538, producing a plume of vapor shown at 539 in FIG. 10. Plume 539 strikes substrate 540 and is deposited onto it as a layer of gallium and indium. As the substrate continues its travel, it encounters monitoring instrument station 544. Monitoring instrument station 544 includes any suitable instrument or instruments configured to measure the layers deposited onto substrate 540. As previously described, this may include X-ray Fluorescence, Atomic Absorption Spectroscopy, and/or any other suitable instrument. Information from monitoring instrument station 544 is fed to monitoring and feedback processor 548, which may be configured to calculate various analytical characteristics, compare the characteristics to desired parameters, and provide output signals to adjust individual heating of each crucible in response to the results obtained. For example, if a GGI ratio in the deposited layer is lower than desired, heating in one or more gallium crucibles may be increased to compensate. In similar fashion, if overall layer thickness is low, temperatures in crucibles of both indium and gallium may be increased, or alternatively, substrate web speed may be decreased. Information and monitoring station 540 may also perform other functions as well, such as providing human readable display of various characteristic values, alarms or warnings, and/or monitoring and control of various other aspects of the overall apparatus.

The methods, systems, and devices described in this disclosure have been exemplified with respect to deposition of gallium and indium. The same or similar principals may be useful for depositing other materials to produce photovoltaic devices. For example mixing schemes and configurations described herein may be used to deposit combinations of tellurium and cadmium, or copper, zinc, and tin. It should also be appreciated that the same principals may be applied to deposit mixtures of more than two substances. For example, a manifold may be configured to receive, mix, and effuse three or more substances from three or more sources, each with independent temperature control.

The disclosure set forth above may encompass multiple distinct inventions with independent utility. Although each of these inventions has been disclosed in its preferred form(s), the specific embodiments thereof as disclosed and illustrated herein are not to be considered in a limiting sense, because numerous variations are possible. The subject matter of the inventions includes all novel and nonobvious combinations and subcombinations of the various elements, features, functions, and/or properties disclosed herein. For various thin layer deposition applications, different combinations of deposition steps and zones may be used in addition to the specific deposition zone configurations described above. None of the particular steps included in the examples described and illustrated are essential for every application. The order, combination, and number of steps and/or components may be varied for different purposes. Other variables may be controlled via the described monitoring stations, for example speed of web transport, pressure, selenium gas output, web temperature, etc. It may be desirable to use various numbers, combinations, and arrangements of crucibles, mixing manifolds, nozzles, and heating elements for differing applications.

What is claimed is:

1. A vapor deposition apparatus for use in manufacturing thin-film photovoltaic semiconductors, comprising:
a roll-to-roll assembly configured to transport a flexible substrate through plural zones along a processing path;
at least one zone having a substantially enclosed gallium and indium deposition assembly configured to deposit a layer comprised of gallium and indium in the presence of selenium gas onto the substrate; and
a crucible containing pre-mixed gallium and indium in a predetermined ratio;
wherein the gallium and indium deposition assembly is configured to deposit gallium and indium evaporated from the crucible.

2. The apparatus of claim 1, further comprising:
a monitoring station configured to monitor amounts of gallium and indium deposited on the substrate.

3. The apparatus of claim 2, wherein the monitoring station includes:
at least one sensor configured to allow measurement of a ratio of gallium and indium; and
at least one processor configured to determine appropriate adjustment of gallium and indium deposition.

4. The apparatus of claim 3, further comprising:
a controller configured to adjust the temperature of the crucible.

5. The apparatus of claim 2, wherein the monitoring station includes:
at least one sensor configured to allow measurement of the thickness of gallium and indium deposited on the substrate; and
at least one processor configured to determine appropriate adjustment of gallium and indium deposition.

6. The apparatus of claim 5, further comprising:
a controller configured to adjust the temperature of the crucible.

7. An apparatus for depositing a mixture of gallium and indium onto a flexible substrate, comprising:
a first crucible containing pre-mixed gallium and indium and a heating element in thermal communication with the crucible;
a vapor manifold connected to the crucible such that vapor may pass from the crucible to the manifold; and
a nozzle connected to the manifold through which a heated mixed gallium and indium vapor exits the source.

8. The apparatus of claim 7, wherein the heating element is disposed in an upper portion of the apparatus.

9. The apparatus of claim 7, wherein the nozzle is formed at least in part by the heating element.

10. The apparatus of claim 7, further comprising a second crucible containing a material selected from the set consisting of gallium and indium, and wherein the first and second crucibles are collectively configured to deposit gallium and indium onto the substrate with a gallium to gallium indium ratio in the range of 25%-35% at a top surface of the deposited layers.

11. The apparatus of claim 10, wherein the first and second crucibles are collectively configured to deposit gallium and indium onto the substrate with a gallium to gallium indium ratio in the range of 25%-35% in a region extending between a depth of 0.6 μm below the top surface and a depth of 1.0 μm below the top surface.

12. A vapor deposition apparatus for use in manufacturing thin-film photovoltaic semiconductors, comprising:
a roll-to-roll assembly configured to transport a flexible substrate through plural zones along a processing path;
a first gallium and indium deposition assembly configured to deposit a first layer including gallium and indium onto the substrate by evaporating pre-mixed gallium and indium from a first crucible in a first predetermined gallium to gallium indium ratio; and
a second gallium and indium deposition assembly configured to deposit a second layer including gallium and indium onto the first layer by evaporating pre-mixed gallium and indium from a second crucible in a second predetermined gallium to gallium indium ratio.

13. The apparatus of claim 12, wherein the first gallium to gallium indium ratio is smaller than the second gallium to gallium indium ratio.

14. The apparatus of claim 12, wherein the second gallium to gallium indium ratio is in the range of 10% to 45%.

15. The apparatus of claim 12, wherein the second gallium to gallium indium ratio is in the range of 25% to 35%.

16. The apparatus of claim 12, wherein the first and second gallium and indium deposition assemblies are collectively configured to produce a gallium to gallium indium ratio in the range of 25%-35% at a top surface of the deposited layers.

17. The apparatus of claim 16, wherein the first and second gallium and indium deposition assemblies are collectively configured to produce a local minimum gallium to gallium indium ratio in the range of 20%-30% at depths between 0.4 μm and 0.5 μm below the top surface.

18. The apparatus of claim 17, wherein the first and second gallium and indium deposition assemblies are collectively configured to produce a maximum gallium to gallium indium ratio of between 0.4 and 0.5.

19. The apparatus of claim 18, wherein the first and second gallium and indium deposition assemblies are collectively configured to produce a gallium to gallium indium ratio that declines slightly between the top surface and a depth of 0.1 μm below the top surface.

20. The apparatus of claim 12, wherein the first and second gallium and indium deposition assemblies are collectively configured to produce a gallium to gallium indium ratio in the range of 25%-35% in a region extending between a depth of 0.6 μm below a top surface of the deposited layers and a depth of 1.0 μm below the top surface.
